(19) United States
(12) Patent Application Publication
(10) Pub. No.: US 2007/0229313 A1
(43) Pub. Date: Oct. 4, 2007

(54) Testing an Electronic Device Having a Keypad by Simultaneously Pressing Several Keys

(75) Inventor: Teunis Den Ouden, Ovar (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/574,594

(22) PCT Filed: Aug. 30, 2005
(86) PCT No.: PCT/IB05/52826

§ 371 Date: Mar. 2, 2007

(30) Foreign Application Priority Data
Sep. 3, 2004 (EP) 04104261.5

(51) Int. Cl. H03M 11/00

(52) U.S. Cl. 341/22

(57) ABSTRACT

The controller of a remote control device is modified to implement a test mode for testing the device's keyboard. During testing, specific ones of the keys are pressed in parallel in selected combinations. In response, the controller has the device generate an RC5 frame with information about functioning of keys pressed in parallel. This approach expedites the testing of remote controls.

### FIELD OF THE INVENTION

The invention relates to an electronic device having a plurality of pressable keys. The invention further relates to an electronic circuit with a controller for use in an electronic device with a plurality of keys, and to a method of testing such a device.

### BACKGROUND ART

As part of the manufacturing process each electronic device needs to be tested before it leaves the factory. If the device has keys or buttons (keyboard, keypad) then these have to be tested for correct functionality. The test procedure can be as simple as pressing each key separately and verifying if the result is as expected. This method is, however, not very easy to industrialize. If the device has a microcontroller, the device to be tested can easily be adapted to have functionality during testing different from the functionality of the device in operational use. A test mode enables to use an automated test system to test the keys of the device. The test machine presses keys and receives test data from the device. Pressing keys can be done with, e.g., pneumatic pistons. If the device has means for communication (transmit-only is already enough) then this can be used to transmit the test data to the test machine via, e.g., cable (RS232, USB, etc.), Infra-Red (RC5, IrDa, etc.), RF, audio, etc.

The keys of a device need to be connected to the device's micro controller. Each key can be individually connected to the controller. This means that each key uses one I/O line of the controller. Using one line per key is not very economical and, therefore, a key-matrix is typically being used instead. The keys are then organized in a matrix (key-matrix), using fewer I/O-lines of a controller than are needed for individual connections. The matrix is functionally divided into rows and columns. Each row and each column is individually connected to the controller, and each cross-point of a row and a column accommodates a single key. For example, a key-matrix of six rows and seven columns can accommodate forty-two keys. In operational use of the device the matrix is scanned, e.g., by means of reading the columns sequentially or reading the rows sequentially. In case of sequential reading of the columns, all rows are scanned per column. In case of sequential reading of the rows, all columns are scanned per row.

A disadvantage of a matrix with respect to individual connections per key is the fact that it is not possible with a matrix configuration to unambiguously detect all possible combinations of multiple keys that are pressed simultaneously.

The problem of “ghost-keys” may arise under these circumstances. In the key-matrix as described above, each row and each column is electrically connected with the controller. Without any key pressed, there is no electrical current flowing from any column to any row. If a key is pressed, then that key makes an electrical connection at the cross-point between the associated row and associated column. Now a current can flow from the column of that key to the row of that key. This specific key can be detected since no other combination of a row and a column allows a current to flow. With the key-matrix approach described above it is also possible to correctly detect two simultaneous key presses. When three keys are pressed simultaneously and these keys are located at cross points of two columns AND two rows then it is impossible to detect correctly which three keys have been pressed. The two columns and two rows form an imaginary rectangle in the matrix. The cross-points of the three pressed keys sit at three corners of this rectangle. With these three keys pressed a current flows from each of the two columns to each of the two rows and, therefore, the controller also detects a key pressed at the cross-point of the fourth corner of the rectangle: the “ghost key”. As four keys are being detected and only three have been pressed, it is impossible for the controller to determine which one is the ghost key.

If the device to be tested does not require or allow multiple simultaneous key presses (other than those that avoid ghost keys) there is usually also no reason to prevent or take into account ghost keys.

For more background on “ghost key” detection see, e.g., U.S. Pat. No. 4,888,600, U.S. Pat. No. 5,220,323, all incorporated herein by reference. U.S. Pat. No. 4,888,600 relates to a matrix keyboard system for producing key codes in response to the actuation of key switches. The keyboard system includes ghost key condition detection. In the keyboard system, a group of parallel drive lines and a group of orthogonal parallel sense lines form a matrix, with a key switch being associated with each of the intersection points on the matrix. The drivelines are sequentially activated, and the actuation of a key switch along an activated driveline results in the coupling of a drive signal to the associated sense line. A ghost key condition arises when three of the four corners of a notional rectangle in the matrix contain an actuated key switch. The ghost key condition detector senses the presence of drive signals not only on the sense lines but also on the drive lines, with a ghost key condition being identified if a drive signal is sensed on two or more sense lines and two or more drive lines simultaneously. U.S. Pat. No. 5,220,323 relates to a keyboard apparatus that includes a key matrix having key switches disposed at intersections between rows and columns forming a matrix and a control unit for selecting a row and a column of the key matrix to sense a state of a key switch disposed at an intersection of the selected row and the selected column of the key matrix. The apparatus includes a first confirmation unit for sensing, in a first period of time, a key switch state of the key matrix to confirm whether or not two or more depressed keys exist on a row of the key matrix and a second confirmation unit for sensing again, in a second period of time, a key switch state of the key matrix such that when two or more depressed keys exist on a column of the key matrix, a confirmation is made to determine whether or not two or more depressed keys exist on the row on which the key depression is found in the key matrix. The apparatus temporarily reserves, when the first and second confirmation units confirm that two or more depressed keys exist both of the column and the row of the key matrix, a depression processing of a key switch associated with the depressed keys.

### SUMMARY OF THE INVENTION

Testing each key of a device takes a substantial amount of time. When testing simple devices with many keys, testing the keys takes up almost all testing time since there is hardly any other functionality to be tested. Keys in a key matrix are usually tested sequentially. With this test, each key is tested for making and breaking; it also automatically tests for short-circuit between any two lines of the key matrix. Testing one key takes a certain amount of time. This time cannot be reduced further since key bouncing and line capacitance cannot be eliminated. Therefore testing a complete device takes up a defined time period that cannot be shortened using above approach.

The inventor proposes an electronic device having a plurality of keys and configured for being tested, a circuit with a controller for use in such a device, and a test method for electronic devices having a user interface that accommodates keys.

An embodiment of the invention relates to an electronic device comprising a plurality of keys. Each respective one of the keys controls, in operational use of the device, a respective functionality of the device upon being pressed. The device further comprises a controller having a test mode at least during testing, wherein the controller is operative to generate an output indicative of specific ones of the keys being pressed in parallel. The specific keys form a combination that avoids a ghost key effect and that corresponds with an indication in the output.

The invention is based on the insight that the controller, preferably one that also governs operational use of the device, can play a functional role in the test procedure. The controller has a test mode wherein it generates an output per set of specific keys pressed in parallel. This output is used to check whether the specific keys were operating correctly. The specific keys form a combination that avoids a ghost key effect. As the specific keys are being pressed in parallel, they cause the controller in the test mode to generate an output that comprises an indication of this combination. The indication of the combination is determined by a particular one, e.g., the first one or the last one, of the specific keys detected as being pressed in the test mode, or by a method that calculates the most probable combination of the specific keys detected as being pressed in the test mode. Preferably, the output also comprises an indication per specific key tested, e.g., “this key functions correctly” or “this key malfunctions”. If the controller detects a key being pressed that does not belong to this combination, the output signals this as an error. Also, if a specific key of the combination malfunctions, the output signals this as an error.

Another embodiment of the invention relates to an electronic circuit comprising a controller configured for use in an electronic device that has a plurality of keys, each respective one of the keys being for control of a respective functionality of the device upon being pressed in operational use of the device. The controller has a test mode at least during testing of the device, in which the controller is operative to generate an output indicative of specific ones of the keys being pressed in parallel. The controller preferably has the properties and operates according to what has been described above.

Yet another embodiment relates to a method of testing an electronic device that comprises a plurality of keys, wherein each respective one thereof controls a respective functionality of the device upon being pressed in operational use of the device. The method comprises causing the device to generate an output indicative of specific ones of the keys being pressed in parallel; receiving the output; and analyzing the output to determine proper functioning or malfunctioning of the specific keys. Preferably, the method comprises putting the device into and/or out of a mode of operation wherein multiple keys being pressed in parallel cause the device to generate the output.

### BRIEF DESCRIPTION OF THE DRAWING

The invention is explained in further detail, by way of example and with reference to the accompanying drawing wherein:

FIG. 1 is a block diagram of a test system in the invention;

FIG. 2 gives the configuration of a conventional RC5 frame;

FIG. 3 gives the configuration of a modified RC5 frame for use in the invention;

FIG. 4 is a diagram of a key matrix with combination labels;

FIG. 5 is a table of RC5 frames in the test mode of a properly functioning device; and

FIG. 6 is a table of RC5 frames in the test mode of a malfunctioning device.

Throughout the Figures, same reference numerals indicate similar or corresponding features.

### DETAILED EMBODIMENTS

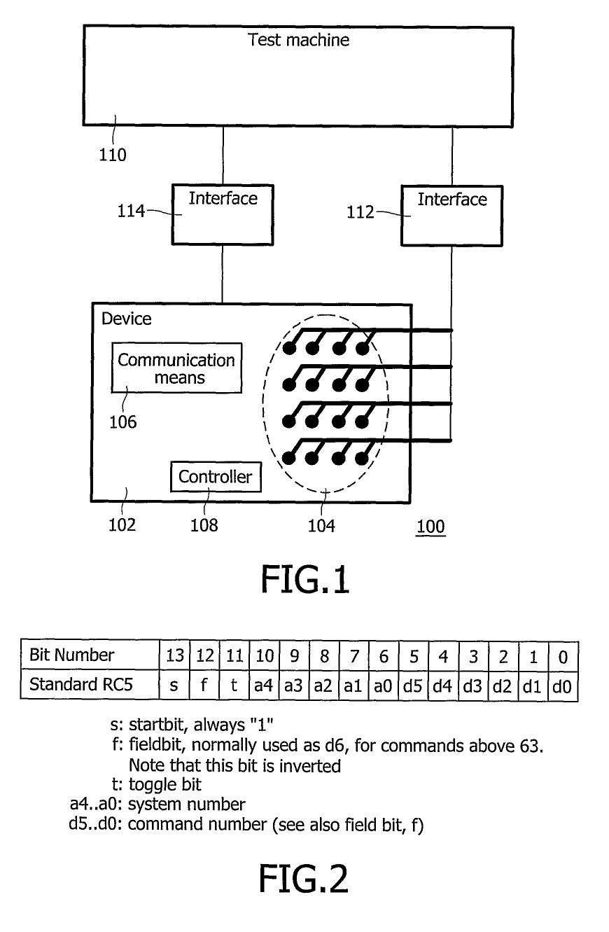

FIG. 1 is a block diagram of a test system 100 in the invention. System 100 comprises an electronic device 102 with a plurality of keys 104. Device 102 comprises, e.g., a remote control device for control of consumer electronics (CE) equipment. Each one of keys 104 invokes a respective control functionality of device 102 upon being pressed in operational use of device 102. For example, one key may implement the “channel-up” functionality, another the “channel-down” functionality, yet another is the “mute” button. Some of the control functionalities may require a certain combination of keys to be pressed in sequence or together. For remote control of compatible CE equipment (not shown), device 102 has communication means 106, e.g., comprising an infrared (IR) transmitter or a radio-frequency (RF) transmitter. Device 102 further has a controller 108 that converts the key presses into IR or RF commands in operational use of device 102.

Test system 100 further comprises a test machine 110 that interacts with device 102 in order to verify correct functioning of device 102. To this end, machine 110 actuates one or more of keys 104 via an interface 112, e.g., comprising pneumatic pistons (not shown). The number of pistons may be equal to the number of keys 104, or the number of pistons may be lower than the number of keys 104 as will be illustrated further below. The response of device 102 to its keys 104 being actuated is communicated to machine 110 via an interface 114. In case device 102 comprises a remote control, interface 114 comprises an IR or RF receiver. Alternatively, interface 114 has a direct electrical connection with controller 108, e.g., via a cable, to communicate the test response to machine 110 as an electrical signal.

Multiple ones of keys 104 can be tested in parallel to reduce the total test time per device at the manufacturer as has been discussed above. Controller 108 in device 102 to be tested has a mode for operational use of device 102, as well as a test mode. In the test mode, controller 108 causes device 102 to send test information to test machine 110. Controller 108 scans keys 104 in a particular pattern depending on the organization of the keys, e.g., a key-matrix. In the matrix, controller 108 uses a key-scan procedure that scans the columns sequentially. Per scan controller 108 reads all rows, and detects a key press if the column scan signal is read back via a row.

Test machine 110 presses multiple ones of keys 104 simultaneously via interface 112. Machine 110 presses and releases enough combinations of keys 104 to test all keys just once. The specific ones of keys 104 that can be pressed simultaneously do not include combinations that can give rise to “ghost key” detections. The ghost key concept is described above. Preferably, the possible key combinations are predefined and are known by both test machine 110 and device to be tested 102 (or the algorithm to calculate the combinations is known). For example, in a six by seven key matrix there will be seven (or six) combinations.

Key presses at device 102 start the key scan procedure. The initial key detected as being pressed during the key scan defines the combination of multiple keys that are expected. Data representative of the combination and the status of all keys that are detected during the key scan and that fit in the combination is sent to test machine 110. Test machine 110 compares the data received with the data stored in its memory (not shown). If the data match then the specific keys in that combination are considered to have operated correctly. If the data does not match, then device 102 is rejected as malfunctioning. If one or more particular keys are detected during the scan that differ from the combination of specific keys expected, then machine 110 is notified of this event as well and device 102 is considered to malfunction.

The following describes an implementation of the invention for a system 100 that tests the keys of a remote control device 102. Test machine 110 transports remote control devices, applies power to them, presses keys 104, receives test data from remote control 102 subjected to the test, and rejects or lets device 102 pass. Device 102 has, besides its normal operational function, also a factory mode program programmed in the ROM of controller 108. The default protocol for the factory mode is IR RC5, but the test method works in principle with any medium and any protocol that communicates data. RC5 has a system field and a command field, see FIG. 2 for the standard definition of an RC5 frame.

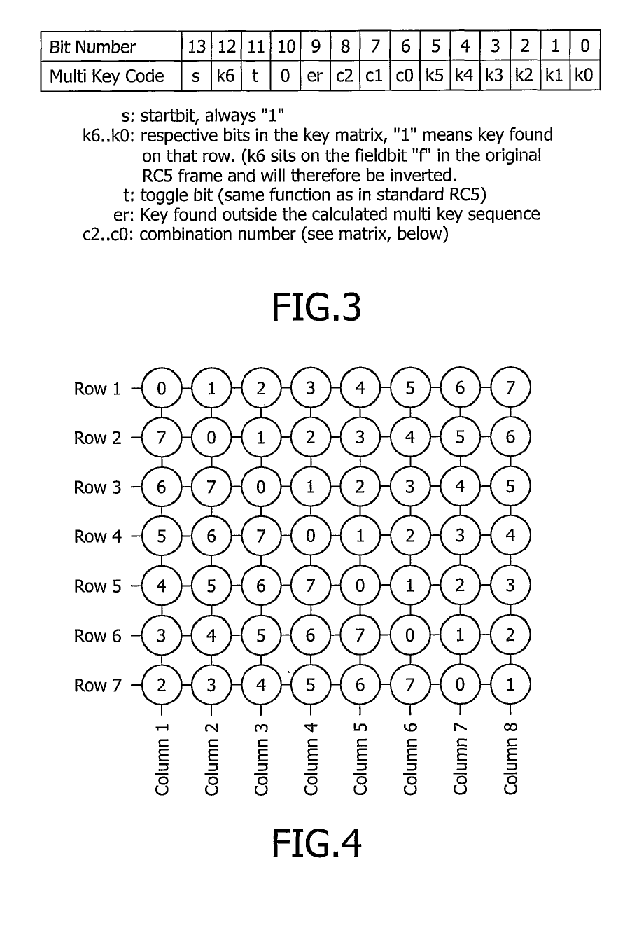

RC5 has not been made for transmitting the commands of more than one key in one frame. Therefore the protocol as used in the test mode in the invention is slightly modified. See FIG. 3. The modified protocol is, however, still readable by any standard RC5 decoder. The system field will be used to transmit a combination indicator (combination number) and an error bit. The combination number is an indication of specific ones of keys 104 intended for being pressed in parallel. The command field has a single bit reserved for each specific key in the combination in the system field.

As for the combination number, reference is made to the example of FIG. 4. FIG. 4 shows keys 104 organized in a matrix of eight columns by seven rows, each thereof being indicated as such in the drawing. As discussed above, a combination of specific ones among keys 104 can be tested in parallel if ghost key effects are avoided, and if the signals detected by controller 108 during the scan are not weak due to, e.g., the current input to a column being distributed between too many columns when too many keys in the same column are being pressed simultaneously. Each combination in the example has been given an integer number (0 to 7). All specific keys belonging to a particular combination have been numbered as indicated in FIG. 4. For example, the keys with the number 6 belong to combination 6. Each combination guarantees that there are no ghost keys.

Per key-scan, all keys of a particular combination are actuated. The key-scan first scans all keys per single row (row 1 first), and per row column 1 is read first. This process implies that keys 104 are scanned one after another in a certain pattern. The first key encountered with the status “being pressed” or “active” defines the combination number that is expected in a correctly functioning device 102. For example, if the key with coordinates [row 2, column 3] is the first key found during a key scan, then the rest of the keys will be checked for combination number being 1. The output for each multiple key press is a “multiple key press code” frame as defined in FIG. 3. Each key found during the key scan and fitting in the expected combination will set a bit in the “multiple key press code” command field. In the example above, wherein combination number 1 is determined for [row 2, column 3], bit k1 is set to “1”. If in the same key scan also the keys at [row 4, column 5]; [row 6, column 7]; and [row 7, column 8] are found then also bits k3, k5 and k6 are set. All keys in the combination that are not detected as being actuated have their corresponding bit in the command field set to “0”. If there is any key found as being actuated that does not correspond with the combination under consideration, then bit “er” (error) is set. This then indicates that there is a short circuit in the remote control (assuming that the test machine did press the correct combination of specific keys).

If device 102 has indeed fifty-six keys organized as in FIG. 4, then the test procedure runs for example as follows:

First step: Transport device 102 to a location under the pistons of interface 112.

Second step: Power up device 102 and put device 102 into the test mode.

Third step: Have test machine 110 press specific ones of keys 104 by activating the proper pistons, e.g., all keys with indication “0” in FIG. 4. In response, device 102 transmits an RC5 code via interface 114 with all k6 . . . k0 bits set, the c field set to 0 (i.e., the combination number) and the error bit “er” reset. The toggle bit “t” and the start bit “s” keep their original function. The complete frame transmitted is: 1 0 0 00000 111111. An RC5 decoder (not shown) in machine 110 will indicate 00.127 (decimal numbers). Test machine 110 receives the RC5 frame from device 102 and compares this frame with a table in its memory. In this case, machine 110 decides that the seven keys in combination “0” are finctioning correctly.

Fourth step Release the specific keys of combination “0” and press all specific keys of combination “1” that are indicated as such in FIG. 4. Again device 102 responds to the key presses and now sends out an IR-frame: 1 0 1 00001 111111 (or 01.127 in decimal format). This frame indicates that all specific keys of combination “1” are found and no other key is found. Note that the toggle bit has changed: this is similar to the original finction in RC5. Test machine 110 receives the IR transmission and decides that for combination “1” also all keys are functioning correctly.

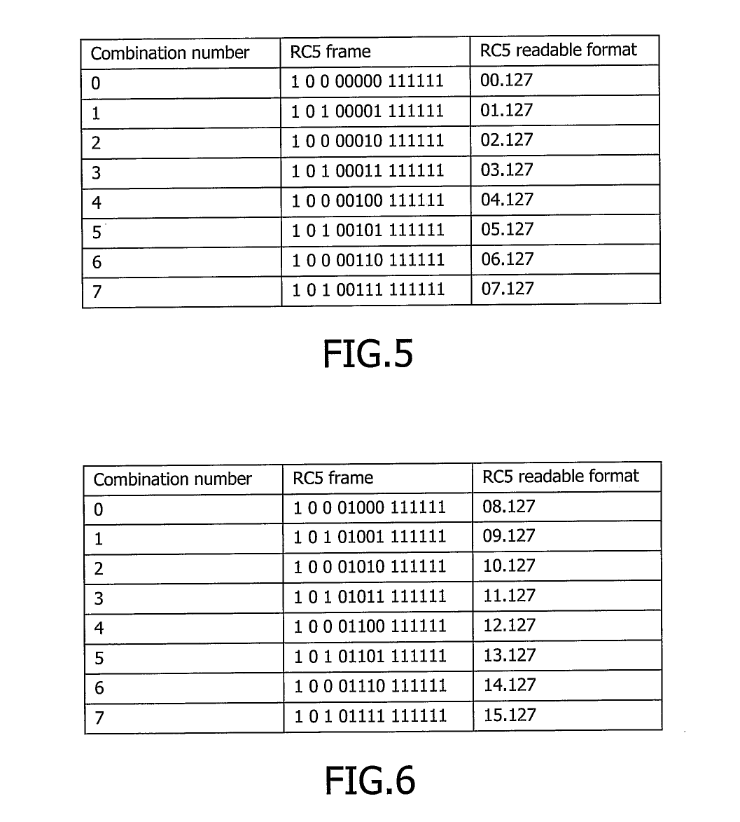

Fifth step: Same as in the fourth step above for all specific keys of combination “2”, “3”, “4”, “5”, “6” or “7”. The respective RC5 frames are given in the table of FIG. 5.

Sixth step: After the last combination test machine 110 passes or rejects device 102. If all specific keys of all combinations were found and the error bit was never set, then device 102 has passed, at least for the key test.

Seventh step: Transport device 102 further with the indication “passed”.

If in above procedure one of keys 104 is malfunctioning, then the respective bit will not be set and test machine 110 rejects device 102. Rejection is based on the discrepancy between the data in the RC5 frame received and the data expected (i.e., as stored in the memory of test machine 110. For example: if the key at [row4, column2] in FIG. 4 is broken, then the RC5 frame for combination “6” equals: 1 0 0 00110 110111 (or 06.119 in decimal format). However, test machine 110 expects 1 0 0 00110 111111 (or 06.127 in decimal format) and therefore rejects device 102. Test machine 110 preferably indicates to the rework technician which key has failed.

A short-circuit between two columns or two rows is also detected by test machine 110. For example: assume there is a short-circuit between column 3 and column 4 in the configuration of FIG. 4. Test machine 110 starts and causes the specific keys of combination “0” to be pressed. In response, device 102 starts a key scan and finds indeed all specific keys of combination “0”, but also the keys at the [row4, column 3] and [row3, column 4]. The latter keys belong to combination “7” and combination “1”, respectively. Controller 108 detects that keys other than the specific keys of combination “0” are pressed (as a result of the short-circuit), and therefore will set the error bit “er” in the RC5 frame for this combination “0”. Similarly, controller 108 will in this scenario detect two more keys for any combination number except for combination “3”. For this combination “3”, controller 108 will find only one extra key, but controller 108 will still set the error bit. The transmitted RC5 frames in this case are as given in the table of FIG. 6.

Test machine 110 receives the frames with the error bit set and will therefore reject device 102. Other errors can be detected and processed as well, as is clear to the skilled person.

The invention as illustrated above expedites automated testing of IR remote controls. Test time for a typical remote control is reduced dramatically. With this improvement test system 100 is not the bottleneck anymore in the manufacturing line. Line output can now be increased without building extra, parallel, test machines. The advantages of the invention increase with increasing number of keys.

The invention is not limited to the RC5 protocol or to a wireless protocol, nor to a remote control device. Any other device with keys in the user interface, a controller and program memory for storing the test mode program, can be tested according to the invention: PC keyboards, cell phones, calculators, PDAs, laptops, label printers, etc.

1. An electronic device, comprising:
a plurality of keys, each respective one for control of a respective functionality of the device upon being pressed in operational use of the device; and
a controller having a test mode different from a further mode for operational use of the device, the test mode being for testing a correct operation of the keys, wherein the controller is operative to generate an output indicative of specific ones of the keys being pressed in parallel.

2. The device of claim 1, wherein:
the specific keys form a combination that avoids a ghost key effect; and
the output comprises an indication of the combination.

3. The device of claim 2, wherein the indication of the combination is determined by a particular one of the specific keys detected as being pressed in the test mode.

4. The device of claim 1, wherein the output comprises an indication per specific key tested.

5. The device of claim 1, wherein the controller has another mode wherein the controller is operative to control the operational use of the device.

6. The device of claim 1, comprising a remote control for control of electronic equipment.

7. An electronic circuit comprising a controller configured for use in an electronic device that has a plurality of keys, each respective one of the keys being for control of a respective functionality of the device upon being pressed in operational use of the device, wherein the controller has a test mode different from a further mode for operational use of the device, the test mode being for testing a correct operation of the keys, and wherein in the test mode the controller is operative to generate an output indicative of specific ones of the keys being pressed in parallel.

8. The circuit of claim 7, wherein:
the specific keys form a combination that avoids a ghost key effect; and
the output comprises an indication of the combination.

9. The circuit of claim 8, wherein the indication of the combination is determined by a particular one of the specific keys detected as being pressed in the test mode.

10. The circuit of claim 7, wherein the output comprises an indication per specific key tested.

11. The circuit of claim 7, wherein the controller has another mode wherein the controller is operative to control the operational use of the device.

12. A method of testing an electronic device that comprises a plurality of keys, each respective one for control of a respective functionality of the device upon being pressed in operational use of the device, the method comprising:
causing the device to assume a test mode, differet from a further mode for operational use of the device, and causing the device in the test mode to generate an output indicative of specific ones of the keys being pressed in parallel;
receiving the output; and
analyzing the output to determine proper functioning or malfunctioning of the specific keys.

13. The method of claim 12, comprising putting the device into and/or out of a mode of operation wherein the specific keys being pressed in parallel cause the device to generate the output.
